(19) United States
(12) Patent Application Publication
(10) Pub. No.: US 2024/0320402 A1
(43) Pub. Date: Sep. 26, 2024

(54) METHOD, DEVICE, AND SYSTEM FOR ESTIMATING THRESHOLD VALUE OF KERNEL DENSITY FUNCTION WITH RESPECT TO DEFECT OF PRODUCT

(71) Applicant: SAMSUNG ELECTRONICS CO., LTD., Suwon-si (KR)

(72) Inventors: Sangjune Bae, Suwon-si (KR); Taeyoon An, Suwon-si (KR); Joohyung You, Suwon-si (KR); In Huh, Suwon-si (KR); Moonhyun Cha, Suwon-si (KR); Jaemyung Choe, Suwon-si (KR)

(21) Appl. No.: 18/544,065

(22) Filed: Dec. 18, 2023

(30) Foreign Application Priority Data
Mar. 24, 2023 (KR) 10-2023-0039270
May 19, 2023 (KR) 10-2023-0065236

(51) Int. Cl. G06F 30/27

(52) U.S. Cl. CPC G06F 30/27

(57) ABSTRACT

Provided are a method, a device, and a system for estimating threshold values of a kernel density function with respect to defects of a product. The method includes a bootstrapping sampling operation, estimating optimal kernel bandwidths for sample data sets by using a bandwidth estimation method selected according to a number of sample data from among a plurality of bandwidth estimation methods, estimating threshold values corresponding to a tail region of the kernel density function based on the optimal kernel bandwidths, and providing a quantitative value for quantifying uncertainty of the threshold values based on the plurality of threshold values.

### CROSS-REFERENCE TO RELATED APPLICATION

This application is based on and claims priority under 35 U.S.C. § 119 to Korean Patent Application Nos. 10-2023-0039270, filed on Mar. 24, 2023, and 10-2023-0065236, filed on May 19, 2023, in the Korean Intellectual Property Office, the disclosures of which are incorporated by reference herein in their entireties.

### BACKGROUND

In the process of product development, it is important to detect defects of a product. To detect defects of a product, a method of estimating threshold values corresponding to a tail region of a probability density function (PDF) of a characteristic parameter of the product and detecting defects of the product using the estimated threshold values may be used. To reduce the time and cost for product development, it may be desirable to accurately and quickly estimate the threshold values of the characteristic parameter of the product. However, as products are becoming miniaturized and the manufacturing process becomes complicated, the number of cases for determining the characteristic parameter increases, and accordingly, the turn-around time (TAT) of simulation increases, the number of sample data for estimating the threshold values increases, and the time and cost for product development increase.

To estimate the tail region of the PDF, a method of optimizing parameters using a maximum likelihood estimator (MLE) by assuming a population distribution may be used. However, this method of optimizing parameters by using the MLE may be difficult to apply to the characteristic parameter distribution of a semiconductor device such as DRAM since it is difficult to assume that the characteristic parameter distribution of the semiconductor device such as DRAM is a one-parameterized distribution according to the characteristic parameters. It is possible to apply parameterized distributions to the distribution of threshold values or extreme values, but there is a problem in that the estimation accuracy can be guaranteed only when the assumption for each distribution is valid.

### SUMMARY

The inventive concept provides a method, a device, and a system for selecting an optimal bandwidth estimation method for estimating threshold values of a kernel density function according to the number of sample data.

The inventive concept also provides a method, a device, and a system for estimating the threshold values, tail region, and kernel bandwidth of the kernel density function even with a relatively small number of sample data.

According to an aspect of the inventive concept, there is provided a method including a bootstrapping sampling operation of sampling a plurality of sample data sets based on a simulation data set including a plurality of simulation data for a characteristic parameter of a product, a kernel bandwidth optimization operation of estimating an optimal kernel bandwidth for each sample data set by using a bandwidth estimation method selected according to the number of sample data included in each sample data set from among a plurality of bandwidth estimation methods for optimizing a kernel bandwidth of a kernel density function with respect to defects of the product, a threshold value estimation operation of estimating a threshold value corresponding to a tail region of the kernel density function for each of the plurality of sample data sets based on optimal kernel bandwidths estimated for each of the plurality of sample data sets, and a quantification operation of providing a quantitative value in which the uncertainty of the threshold values corresponding to the tail region of the kernel density function is quantified, based on the threshold values of the plurality of sample data sets.

According to another aspect of the inventive concept, there is provided a device including a sampling module configured to sample a plurality of sample data sets based on a simulation data set generated as a simulation result of a characteristic parameter of a product, an optimization module configured to estimate an optimal kernel bandwidth for each sample data set by using a bandwidth estimation method selected according to the number of sample data included in each sample data set from among a plurality of bandwidth estimation methods for optimizing a kernel bandwidth of a kernel density function with respect to defects of the product, an estimation module configured to estimate a threshold value corresponding to a tail region of the kernel density function for each of the plurality of sample data sets based on optimal kernel bandwidths estimated for each of the plurality of sample data sets, and a quantification module configured to provide a quantitative value in which the uncertainty of the threshold values corresponding to a tail region of the kernel density function is quantified, based on the threshold values of the plurality of sample data sets.

According to another aspect of the inventive concept, there is provided a system including a simulation device configured to generate a simulation data set including a plurality of simulation data for a characteristic parameter of a product by performing simulation on the characteristic parameter of the product, and an estimation device configured to estimate threshold values corresponding to a tail region of a kernel density function with respect to defects of the product based on the simulation data set, wherein the estimation device is configured to sample a plurality of sample data sets from the simulation data set, estimate an optimal kernel bandwidth for each sample data set by using a bandwidth estimation method selected according to the number of sample data included in each sample data set from among a plurality of bandwidth estimation methods for optimizing the kernel bandwidth of the kernel density function, estimate the threshold value for each of the plurality of sample data sets based on optimal kernel bandwidths estimated for each of the plurality of sample data sets, and generate a quantitative value quantifying the uncertainty of the threshold values based on the threshold values of the plurality of sample data sets.

According to another aspect of the inventive concept, there is provided a method including sampling a plurality of sample data sets based on a simulation data set including a plurality of simulation data for a characteristic parameter of a product, estimating an optimal kernel bandwidth for each sample data set using a method selected according to the number of sample data included in each sample data set from among a plug-in rule method and a least square cross validation method for optimizing a kernel bandwidth of a kernel density function with respect to defects of the product, estimating a threshold value corresponding to a tail region of the kernel density function for each of the plurality of sample data sets based on optimal kernel bandwidths estimated for each of the plurality of sample data sets, and providing a quantitative value in which the uncertainty of the threshold values is quantified based on the threshold values of the plurality of sample data sets.

### BRIEF DESCRIPTION OF THE DRAWINGS

Implementations will be more clearly understood from the following detailed description taken in conjunction with the accompanying drawings in which:

FIG. 1 is a diagram of a system according to some implementations;

FIG. 2 is a diagram of an estimation device according to some implementations;

FIGS. 3A and 3B are diagrams that compare techniques of generating sample data according to some implementations;

FIG. 4 is a graph illustrating kernel functions according to some implementations;

FIG. 5 is a graph illustrating an original kernel density function, a transformed kernel density function, and a true PDF, according to some implementations;

FIG. 6 is a graph illustrating a change in a kernel density function according to a kernel bandwidth according to some implementations;

FIG. 7 is a diagram of an optimization module according to some implementations;

FIG. 8 is a graph illustrating a kernel bandwidth and a threshold estimation accuracy according to a bandwidth estimation method, according to some implementations;

FIG. 9 is a graph illustrating threshold values according to the number of sample data according to some implementations;

FIG. 10 is a chart showing a mean location, a standard deviation, a total calculation time, and a mean error of threshold values according to the number of sample data according to some implementations;

FIG. 11 is a flowchart for illustrating a method according to some implementations;

FIG. 12 is a flowchart for illustrating some implementations of operation S1110;

FIG. 13 is a flowchart for illustrating some implementations of operation S1120;

FIG. 14 is a flowchart for illustrating some implementations of operation S1320;

FIG. 15 is a flowchart for illustrating some implementations of operation S1340;

FIG. 16 is a flowchart for illustrating a method according to some implementations; and

FIG. 17 is a flowchart for illustrating a method according to some implementations.

### DETAILED DESCRIPTION

Hereinafter, implementations will be described in detail with reference to the accompanying drawings.

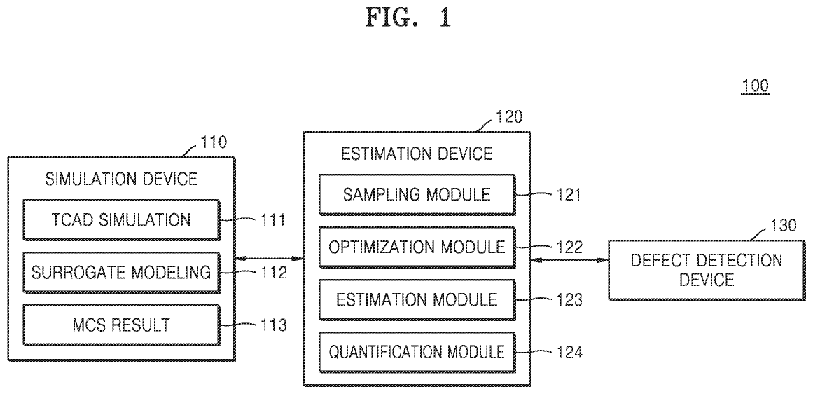

FIG. 1 is a diagram of a system according to some implementations.

Referring to FIG. 1, a system 100 includes a simulation device 110, an estimation device 120, and a defect detection device 130.

The simulation device 110 is configured to perform a simulation regarding a characteristic parameter of a product.

The product may include a semiconductor device or a non-semiconductor device. In some implementations, the product includes a memory device. According to some implementations, the memory device includes a volatile memory device or a non-volatile memory device. The non-volatile memory device may include, for example, dynamic random access memory (DRAM), synchronous DRAM (SDRAM), double data rate (DDR) SDRAM, low power double data rate (LPDDR) SDRAM, graphics double data rate (GDDR) SDRAM, DDR2 SDRAM, DDR3 SDRAM, DDR4 SDRAM, DDR5 SDRAM, low power double data rate 4th generation (LPDDR4) DRAM, low power double data rate 5th generation (LPDDR 5) DRAM, and the like. The non-volatile memory may include flash memory, read only memory (ROM), magnetic RAM (MRAM), spin-transfer torque MRAM, conductive bridging RAM (CBRAM), ferroelectric RAM (FeRAM), and phase-change RAM (PRAM). According to some implementations, the product includes a non-memory device. The non-memory device may include, for example, a processor such as a central processing unit, a neural network processing unit, or a graphics processing unit, an image sensor, a power management integrated circuit, and the like.

The characteristic parameter of the product may include a physical quantity, a physical characteristic, and a physical parameter of the product. In some implementations, when the product is DRAM, the characteristic parameter of the DRAM includes, for example, Rtotal, tRDL, tREF, and the like. The Rtotal may be a parameter indicating the sum of parasitic resistance and channel resistance included in the DRAM. The tRDL may be a parameter indicating an allowable time interval between data-in and word-line precharge or a parameter indicating a last data-in to PRE command period. The tREF may be a parameter indicating a refresh cycle. However, the characteristic parameter is not limited to the Rtotal, tRDL, and tREF.

The simulation device 110 may generate a simulation data set by performing a simulation regarding the characteristic parameter of the product. The simulation device 110 may provide the simulation data set to the estimation device 120. The simulation data set may include a plurality of simulation data. The simulation data may be data including samples of the characteristic parameter of the product. In some implementations, when the characteristic parameter of the product is Rtotal, the simulation data includes specific samples of Rtotal. Specifically, for example, first simulation data may include 10⁵ samples of Rtotal, second simulation data may include 10⁶ samples of Rtotal, and third simulation data may include 10⁷ samples of Rtotal. 10⁵, 10⁶, and 10⁷ may each indicate the number of samples of Rtotal.

In some implementations, the simulation device 110 includes a technology computer-aided design (TCAD) simulation unit 111, a surrogate modeling unit 112, and a Monte Carlo simulation (MCS) result unit 113. The TCAD simulation unit 111 may execute TCAD simulation for the characteristic parameter of the product. The surrogate modeling unit 112 may generate a surrogate model based on the TCAD simulation. The surrogate modeling unit 112 may generate samples by sampling data simulated through the surrogate model. The MCS result unit 113 may generate an MCS set by performing MCS on the samples, and may provide the MCS set to the estimation device 120 as the aforementioned simulation data set. The MCS may be a mathematical technique used to estimate the probable outcome of an uncertain event.

The estimation device 120 may be a device for estimating threshold values of a kernel density function based on the kernel density function. The estimation device 120 may estimate a threshold value corresponding to a tail region of the kernel density function with respect to defects of the product based on the simulation data set. The threshold value may be referred to as an extreme value.

In some implementations, the estimation device 120 includes a sampling module 121, an optimization module 122, an estimation module 123, and a quantification module 124.

The sampling module 121 may sample a plurality of sample data sets based on the simulation data set.

The optimization module 122 may estimate an optimal kernel bandwidth for each sample data set by using a bandwidth estimation method selected from among a plurality of bandwidth estimation methods. In some implementations, the optimization module 122 selects the optimal bandwidth estimation method, from among the plurality of bandwidth estimation methods, according to the number of sample data included in each sample data set. The optimal kernel bandwidth may be estimated for each sample data set. That is, the number of optimal kernel bandwidths may correspond to the number of sample data sets. For example, when the number of sample data sets is N (N is an integer greater than or equal to 2), the number of optimal kernel bandwidths may also be N. The bandwidth estimation method may be an algorithm for optimizing a kernel bandwidth of a kernel density function. The kernel bandwidth may also be referred to as a bandwidth.

The estimation module 123 may estimate a threshold value for each of the plurality of sample data sets based on optimal kernel bandwidths estimated for each of the plurality of sample data sets. For example, when the number of sample data sets is N, the number of threshold values may also be N.

The quantification module 124 may generate a quantitative value quantifying the uncertainty of the threshold values based on the threshold values of the plurality of sample data sets. In some implementations, the quantitative value is the mean of the threshold values. For example, the quantification module 124 may calculate the mean of threshold values of the plurality of sample data sets as the quantitative value. In some implementations, the quantitative value is the standard deviation of the threshold values. For example, the quantification module 124 may calculate the standard deviation of the threshold values of the plurality of sample data sets as the quantitative value. In some implementations, the quantification module 124 individually calculates the mean and the standard deviation of the threshold values of the plurality of sample data sets.

As described above, by using the optimal bandwidth estimation method according to the number of sample data, it is possible to accurately estimate the threshold value, tail region, and kernel bandwidth of the kernel density function.

In addition, as described above, by estimating the threshold value, tail region, and kernel bandwidth of the kernel density function even with a relatively small number of sample data, it is possible to reduce turn-around time (TAT) and resources for estimation.

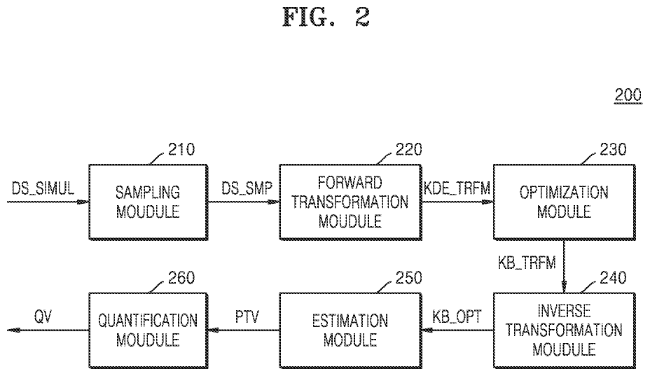

FIG. 2 is a diagram of an estimation device according to some implementations.

Referring to FIG. 2, the estimation device 200 includes a sampling module 210, an optimization module 230, an estimation module 250, and a quantization module 260. In some implementations, to increase the accuracy of the kernel density function, the estimation device 200 further includes a forward transformation module 220 and an inverse transformation module 240.

The sampling module 210 may perform random sampling on a simulation data set DS_SIMUL. The random sampling of the simulation data set DS_SIMUL may be a sampling method for obtaining k sample data from a plurality of simulation data. k may be an integer of 2 or greater. The random sampling of the simulation data set DS_SIMUL may result in generating one sample data set DS_SMP including k sample data. The sampling module 210 may repeatedly perform random sampling N times on the simulation data set DS_SIMUL. The random sampling N times may result in generating N sample data sets DS_SMP.

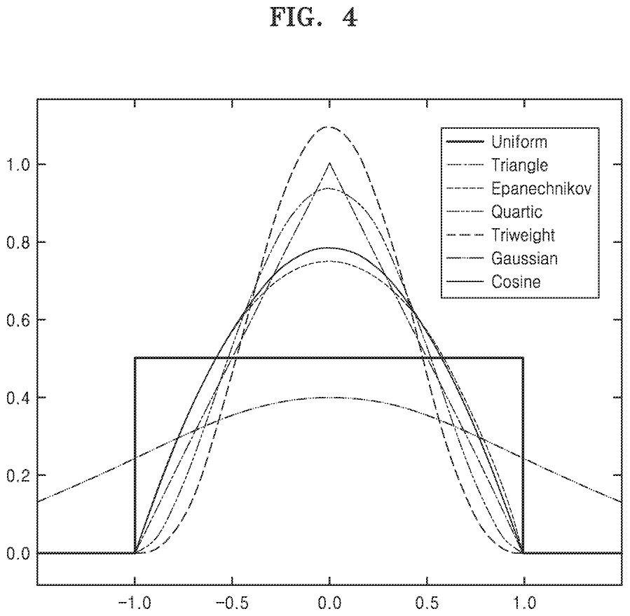

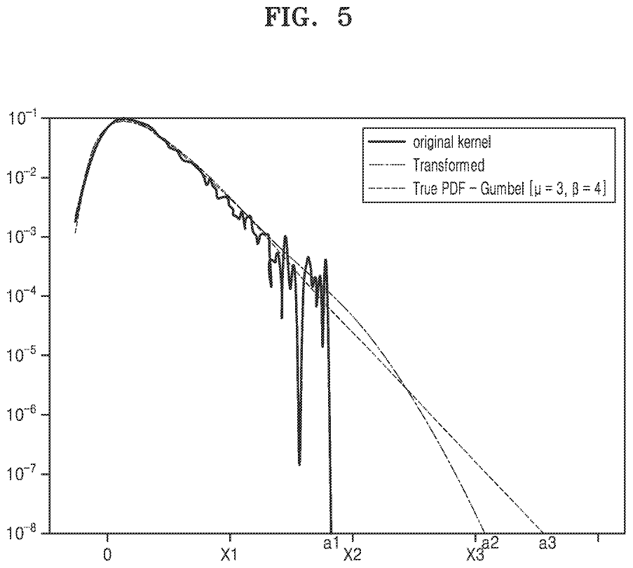

The forward transformation module 220 may set a transformed kernel density function KDE_TRFM defined on the basis of a domain of a transformation function, based on the kernel function for the sample data set DS_SMP and the transformation function. The kernel function is a function for estimating a function value based on a distance between samples, and is described below with reference to FIG. 4. The transformation function may be a function that changes a domain of the kernel function. Some implementations of the transformation function and the forward transformation module 220 are described below with reference to FIG. 5.

The optimization module 230 may check the number of sample data included in the sample data set. The optimization module 230 may set an optimal transformed kernel density function KDE_TRFM according to the number of sample data. The optimization module 230 may optimize a kernel bandwidth KB_TRFM of the optimal transformed kernel density function KDE_TRFM for each sample data set by using the set optimal transformed kernel density function KDE_TRFM.

The inverse transformation module 240 may calculate an optimal kernel bandwidth KB_OPT of the kernel density function from the optimal kernel bandwidth KB_TRFM of the transformed kernel density function KDE_TRFM based on an inverse transformation function corresponding to the transformation function and the kernel function.

The estimation module 250 may estimate a threshold value PTV corresponding to a tail region of the kernel density function based on each optimal kernel bandwidth KB_OPT.

In some implementations, the sampling module 210, the forward transformation module 220, the optimization module 230, the inverse transformation module 240, and the estimation module 250 are configured as an iterative loop. The iterative loop may be repeated N times. When the iterative loop is repeated N times, N kernel bandwidths KB_TRFM and N optimal kernel bandwidths KB_OPT may be calculated, and N threshold values PTVs for N sample data sets DS_SMP may be estimated.

The quantification module 260 may calculate a quantitative value QV based on the plurality of threshold values PTV.

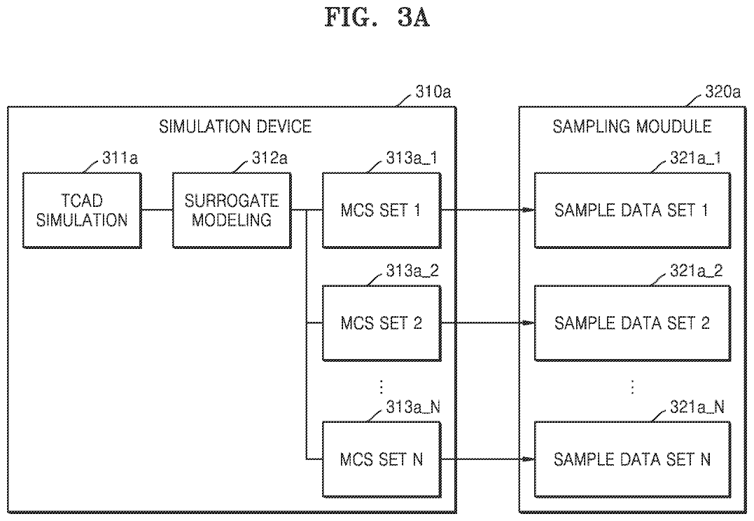

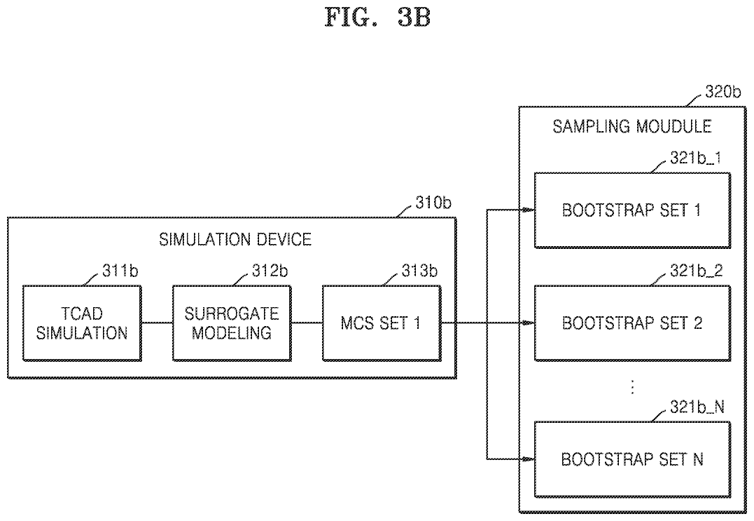

FIGS. 3A and 3B are diagrams that compare techniques of generating sample data according to some implementations. Specifically, FIG. 3A is a diagram of a comparative example of generating sample data, and FIG. 3B is a diagram of some implementations for generating sample data.

To estimate extreme values of the characteristic parameter of the product and quantify the uncertainty of the estimated values, it is desirable to repeat the process of estimating extreme values corresponding to the tail region of the kernel density function using different MCS sets.

For example, to estimate the tail region of the kernel density function for Rtotal of DRAM, in a simulation device 310a according to the comparative example of FIG. 3A, a plurality of MCS sets 313a_1, 313a_2, and 313a_N generated by a TCAD simulation unit 311a and a surrogate modeling unit 312a may be required. Each of the plurality of MCS sets 313a_1, 313a_2, and 313a_N may include as many MCS samples as the number requested by the user. For example, each of the plurality of MCS sets 313a_1, 313a_2, and 313a_N may include 0 (e.g., 10⁷) or more MCS samples. A sampling module 320a according to the comparative example may generate a plurality of sample data sets 321a_1, 321a_2, and 321a_N from the plurality of MCS sets 313a_1, 313a_2, and 313a_N, respectively. However, since one TAT for MCS samples or each MCS set may take up to several hours, the TAT for the plurality of MCS sets 313a_1, 313a_2, and 313a_N may also increase. As a result, since the TAT for the plurality of sample data sets 321a_1, 321a_2, and 321a_N increases, the time required to estimate the tail region of the kernel density function for Rtotal of DRAM may increase.

In a simulation device 310b according to some implementations of FIG. 3B, one MCS set 313b is generated by the TCAD simulation unit 311b and the surrogate modeling unit 312b. The TAT for the MCS set 313b of FIG. 3B may be less than the TAT for the plurality of MCS sets 313a_1, 313a_2, and 313a_N of FIG. 3A. A sampling module 320b according to some implementations is referred to as a bootstrapping module. Bootstrapping, which is a re-sampling method, may refer to a method of repeating a process of extracting and estimating a part of all samples several times, that is, sampling with replacement. The sampling module 320b according to some implementations performs bootstrapping N times for one MCS set 313b. Specifically, the sampling module 320b performs bootstrapping once on the MCS samples included in one MCS set 313b, thereby generating one bootstrap set including k randomly sampled sample data (e.g., MCS samples). The bootstrap set may correspond to the sample data set of FIG. 1. As a result of bootstrapping N times, a plurality of bootstrap sets 321b_1, 321b_2, and 321b_N may be generated. The time required to perform bootstrapping once or N times may be relatively less than one TAT for each MCS set and/or TAT for the plurality of MCS sets 313a_1, 313a_2, and 313a_N.

To prevent excessive TAT consumption in FIG. 3A, as shown in FIG. 3B, the plurality of MCS sets 313a_1, 313a_2, and 313a_N in FIG. 3A may be replaced with generating one MCS set and performing iterative sampling with replacement (e.g., bootstrapping) on the MCS set. Accordingly, the time required to estimate the tail region of the kernel density function for the characteristic parameter (e.g., Rtotal of DRAM) of the product may be reduced.

In some implementations, the sampling module 320b outputs the plurality of bootstrap sets 321b_1, 321b_2, and 321b_N in parallel. In some implementations, the sampling module 320b sequentially outputs the plurality of bootstrap sets 321b_1, 321b_2, and 321b_N.

FIG. 4 is a graph illustrating kernel functions according to some implementations.

Referring to FIG. 4, based on kernel density estimation (KDE), extreme values of the kernel density function and the uncertainty of the extreme values may be estimated. The KDE may be a method of estimating probability distribution characteristics of original variables from the distribution of observed data. The density estimation method may include parametric density estimation and non-parametric density estimation. The parametric density estimation may be a method of optimizing parameters of the population distribution with a maximum likelihood estimator (MLE) by assuming the population distribution to be a specific distribution (Gaussian, Gumbel, etc.) through prior knowledge. The non-parametric density estimation may be a method of estimating a population PDF based only on observed data without prior knowledge. For example, a histogram may be included in the non-parametric density estimation. A discontinuity may appear at the boundary of a bin (binary) in the histogram, and the open shape of the histogram may vary depending on the size and starting position of the bin. The KDE may be an estimation method that improves the characteristics of such a histogram.

The kernel function used in the kernel density function is symmetric about the origin and does not have a negative value, and an integral of the kernel function in a real space may be 1. The type of kernel functions may include, for example, Uniform, Triangle, Epanechnikov, Quartic, Triweight, Gaussian, Cosine, and the like with reference to FIG. 4.

The kernel density function may be expressed as Equation 1 below.

$${\hat{f}}_{h} ( x ) = \frac{1}{n} {\sum }_{i = 1}^{n} {K}_{h} ( x - {x}_{i} ) \qquad [ Equation 1 ]$$

xᵢ (i=1 to n) is observed sample data, x is a value of the characteristic parameter whose density is to be known (e.g., Rtotal of DRAM), K is a kernel function, h is a kernel bandwidth, and n is the number of sample data. n may be the aforementioned k.

FIG. 5 is a graph illustrating an original kernel density function, a transformed kernel density function, and a true PDF.

Referring to FIG. 5, the kernel function is a function for estimating a function value based on a distance between samples of sample data. In general, since the distance between samples for generating a kernel function is long, it may be difficult to accurately estimate an extreme value using only the original kernel function. Therefore, a transformation function that transforms a domain of a variable may be needed to reduce the relative distance between the samples. Implementations relating to the transformation function may be performed in the forward transform module 220.

Referring to FIG. 5, for example, the kernel density function of the true PDF (“True PDF-Gumbel [μ=3, β=4]” shown in FIG. 5) and the original kernel (“Original kernel” shown in FIG. 5) is assumed to be a Gumbel-based distribution. The true PDF of FIG. 5 assumes that μ is 3 and β is 4. In FIG. 5, the x-axis (or horizontal axis) may correspond to variables or characteristic parameter values, and the y-axis (or vertical axis) in FIG. 5 may correspond to function values or probability values. Estimating an extreme value (or threshold value) may refer to estimating a value close to a value (e.g., a3) corresponding to a specific probability value (e.g., 10⁻⁸) of the true PDF. Since the true PDF is a function that can be set up both theoretically and mathematically, it may be difficult to measure or obtain a precise shape of the function. Therefore, it is desirable to find a value very close to the value of the true PDF (e.g., a3) using the kernel density function. However, in the case of the kernel density function of the original kernel, the distance between the samples may be non-equalized. Thus, to increase the accuracy of the kernel density function, a variable transformation method for equalizing the relative distance between the samples may be required. In the variable transformation method, the transformation function described above may be used.

The transformation function may be expressed as a relational expression such as Equation 2 below.

$$y = t ( x ) \qquad [ Equation 2 ]$$

x is a characteristic parameter whose density is to be known (e.g., Rtotal of DRAM), and may correspond to a domain of the original kernel function. y may correspond to a domain of the transformation function. According to the transformation function, the domain of the original kernel function may be changed. This has the advantage of preventing the bumpy behavior of the kernel density function.

In some implementations, the variable transformation is a logarithmic transformation. For example, the transformation function (t(x)) may be a logarithmic function.

When the kernel density function is used by applying the transformation function, the relationship of the kernel density function between the variable y in the transformed domain and the variable x in the original domain, using Equation 1 and Equation 2, may be expressed as Equation 3 below.

$${\hat{f}}_{X} ( x ; h ) = \vert {t}^{′} ( {t}^{- 1} ( y ) ) \vert \frac{1}{n} {\sum }_{i = 1}^{n} {K}_{h} ( y - {Y}_{i} ) \qquad [ Equation 3 ]$$

Yᵢ may be a value derived by substituting xᵢ of Equation 1 into the transformation function. In Equation 3, x; h may be a marker for distinguishing a variable from a constant. According to Equation 3, the domain changed threshold value may be, for example, a2.

After the transformation function is used, the inverse transformation function may transform back to the domain of the original variable. In the inverse transformation function, the process of transforming according to the above-described number of variables may be performed in reverse. Implementations relating to the inverse transformation function may be performed in the inverse transform module 240.

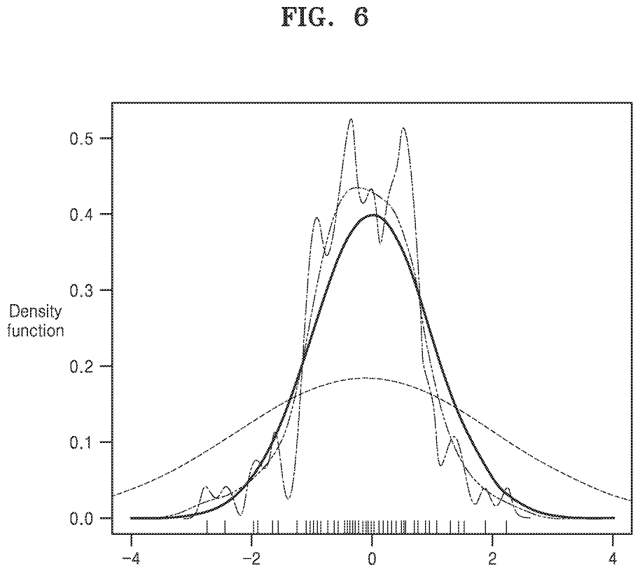

FIG. 6 is a graph illustrating a change in a kernel density function according to a kernel bandwidth.

Referring to FIG. 6, the kernel bandwidth of the kernel density function is the only parameter that determines the shape of the kernel density function when the kernel function is determined. Accordingly, the threshold value may be estimated differently according to the value of the kernel bandwidth. When the kernel bandwidth is too small, the kernel density function may be reliable only for sample data, and the threshold value of the kernel density function may be almost the same as the observed value. When the kernel bandwidth is too high, the kernel density function may not be reliable for the sample data, and the difference between the threshold value of the kernel density function and the observed value may increase.

To determine the kernel bandwidth, an error function is defined (or set). In some implementations, an integrated squared error (ISE) is used for the error function. The ISE of the kernel density function to be used for the error function may be calculated as Equation 4.

$$ISE [ {\hat{f}}_{X} ( x ; h ) ] = \int {( {\hat{f}}_{X} ( x ; h ) - {f}_{X} ( x ) )}^{2} d x \qquad [ Equation 4 ]$$

In Equation 4, \hat{ƒ}ₓ(x; h) is a kernel density function, and ƒₓ (x) is a true PDF (or true function). Equation 4 may be an integral of the difference between the true PDF and the kernel density function. The true PDF may be an unknown function. Since the kernel density function is a function dependent on the location and the number of random samples, Equation 4 may also have random characteristics. Therefore, it is desirable to define a mean integrated squared error (MISE) corresponding to the mean of the ISEs. The MISE of the kernel density function may be calculated as Equation 5.

$$MISE [ {\hat{f}}_{X} ( x ; h ) ] = E [ \int {( {\hat{f}}_{X} ( x ; h ) - {f}_{X} ( x ) )}^{2} d x ] \qquad [ Equation 5 ]$$

where E may be a mathematical symbol representing a mean. When the kernel bandwidth that minimizes the value according to Equation 5 is obtained, the kernel bandwidth may be estimated as the optimal kernel bandwidth, and the threshold value of the kernel density function may be estimated using the optimal kernel bandwidth. Since the true PDF is an unknown function even in Equation 5, it is sometimes difficult to express an explicit equation for the kernel bandwidth. Therefore, it is desirable to search (or acquire) the optimal kernel bandwidth in Equation 5 through the bandwidth estimation method. Hereinafter, implementations for obtaining the optimal kernel bandwidth using the bandwidth estimation method selected according to the number of sample data are described below.

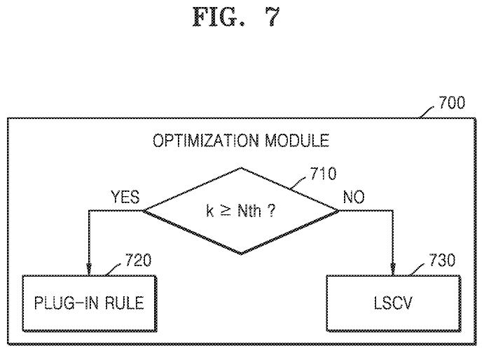

FIG. 7 is a diagram of an optimization module according to some implementations.

Referring to FIG. 7, in some implementations, the optimization module 700 compares the number of sample data included in each sample data set with a reference number (see 710 of FIG. 7). The optimization module 700 may estimate an optimal kernel bandwidth for each sample data set using one of a first bandwidth estimation method and a second bandwidth estimation method selected according to the result of the comparison (see 720 in FIG. 7 or 730 in FIG. 7).

The optimization module 700 may compare the number of sample data included in the sample data set DS_SMP with the reference number. Referring to 710 of FIG. 7, for example, the number of sample data included in the sample data set DS_SMP may be k, and the reference number may be Nth. The optimization module 700 may determine whether k is greater than or equal to Nth.

When the number of sample data included in the sample data set DS_SMP is greater than or equal to the reference number (see 710 YES in FIG. 7), the optimization module 700 may optimize the kernel bandwidth of the kernel density function for the corresponding sample data set DS_SMP by using the first bandwidth estimation method. In some implementations, the first bandwidth estimation method is a plug-in rule method. Referring to 720 of FIG. 7, for example, the optimization module 700 estimates the optimal kernel bandwidth using the plug-in rule method. According to the plug-in rule method, the optimization module 700 may apply Taylor expansion to Equation 5, hypothetically substitute a true PDF corresponding to an unknown curvature into a specific distribution (e.g., Gaussian distribution, etc.) according to prior knowledge, and derive Silverman's rule of thumb to calculate the optimal kernel bandwidth. In some implementations, the kernel bandwidth optimized according to the plug-in rule method is expressed as Equation 6 below.

$$\hat{h} = 1.06 {n}^{- 1 / 5} \hat{σ} \qquad [ Equation 6 ]$$

n is the number of sample data. n may be the aforementioned k. \hat{σ} may be the standard deviation of the sample data.

When the number of sample data included in the sample data set DS_SMP is less than the reference number (see 710 NO in FIG. 7), the optimization module 700 may optimize the kernel bandwidth of the kernel density function for the corresponding sample data set DS_SMP by using the second bandwidth estimation method. In some implementations, the second bandwidth estimation method is a least square cross validation (LSCV) method. Referring to 730 of FIG. 7, for example, the optimization module 700 estimates the optimal kernel bandwidth using the LSCV method. In the LSCV method, when Equation 5 is developed, terms irrelevant to the kernel bandwidth may be eliminated, and the optimal kernel bandwidth may be determined as a value that minimizes Equation 7 below.

$$\hat{h} = arg min E [ \int {{\hat{f}}_{X} ( x ; h )}^{2} d x ] - 2 E [ \int {\hat{f}}_{X} ( x ; h ) f ( x ) d x ] \qquad [ Equation 7 ]$$

In Equation 7, argmin( ) is arguments of min, and may be points or parameters in the domain that make a function a minimum. Since ƒ_{X}(x) is an unknown function in Equation 7, an unbiased estimator may be utilized. The unbiased estimator may refer to a statistic when the expected value of the estimator obtained from samples is the same as the parameter to be estimated. The kernel bandwidth using the unbiased estimator may be calculated as shown in Equation 8 below.

$$\hat{h} = arg min E [ \int {{\hat{f}}_{X} ( x ; h )}^{2} d x ] - 2 {n}^{- 1} {\sum }_{i = 1}^{n} \frac{1}{n - 1} {\sum }_{j = 1 , j \neq i}^{n} {K}_{h} ( x - {X}_{j} ) \qquad [ Equation 8 ]$$

n is the number of sample data. n may be the aforementioned k.

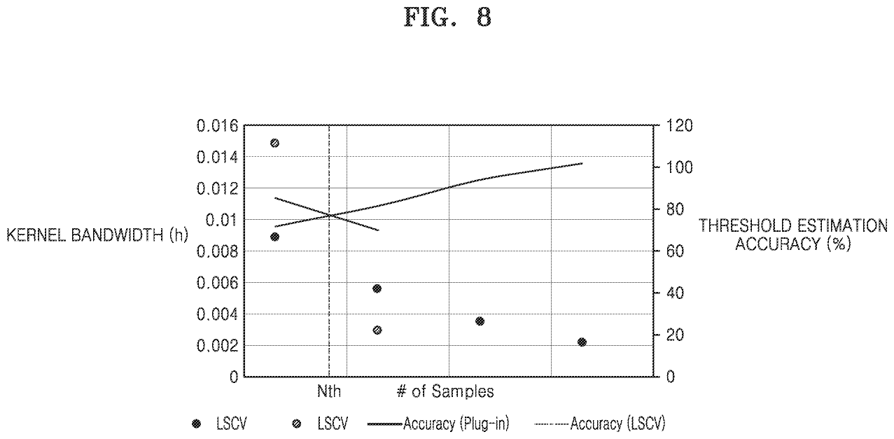

FIG. 8 is a graph illustrating a kernel bandwidth and a threshold estimation accuracy according to a bandwidth estimation method, according to some implementations.

Referring to FIG. 8, when the number of sample data # of Samples is less than the reference number Nth, the value of the kernel bandwidth estimated by the LSCV is greater than the value of the kernel bandwidth estimated by the plug-in rule. As the number of the sample data # of Samples increases, the difference between the kernel bandwidths estimated by the two methods or the difference between the estimated values estimated by the two methods may decrease and each of the kernel bandwidths and the estimated values may be reversed. The characteristic parameter distribution of the product (e.g., Rtotal distribution of DRAM) and the threshold values may be accurately estimated by selecting an appropriate bandwidth estimation method according to the number of sample data # of Samples. For example, when the number of sample data # of Samples is less than the reference number Nth, the accuracy of the values estimated by the LSCV may be relatively greater than the accuracy of the values estimated by the plug-in rule. For another example, when the number of sample data # of Samples is greater than or equal to the reference number Nth, the accuracy of the values estimated by the plug-in rule may be relatively greater than the accuracy of the values estimated by the LSCV.

As described above, the threshold values for a section of all sample data # of samples may be accurately estimated by using an optimal bandwidth estimation method according to the number of sample data # of samples.

In addition, as described above, the time required to estimate the threshold values may be reduced by using the optimal bandwidth estimation method according to the number of sample data # of Samples.

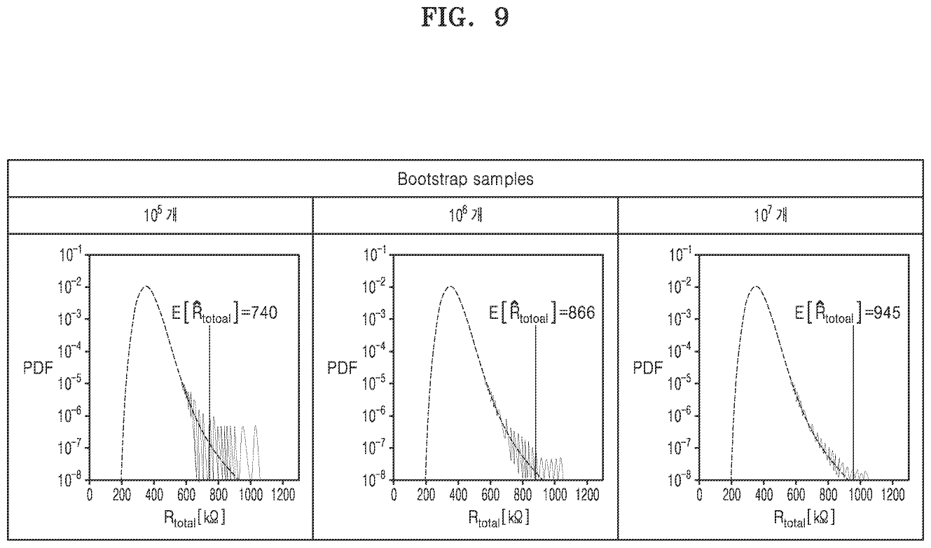

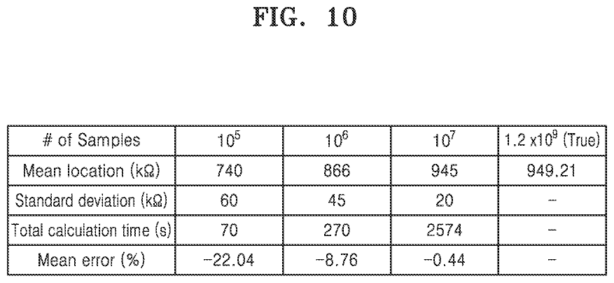

FIG. 9 is a graph illustrating threshold values according to the number of sample data according to some implementations, and FIG. 10 is a chart showing a mean location, a standard deviation, a total calculation time, and a mean error of threshold values according to the number of sample data according to some implementations.

In FIGS. 9 and 10, it is assumed that the characteristic parameter is Rtotal of DRAM.

Referring to FIG. 9, the dotted line graph shown in FIG. 9 represents the true PDF distribution. The solid line graph shown in FIG. 9 is a graph obtained by repeatedly estimating threshold values of the characteristic parameter (e.g., Rtotal of DRAM) using the kernel density function (e.g., 100 iterations of estimation). Referring to the estimation result as an example, when the number of sample data, i.e., the number of bootstrap samples, is 10⁵, the mean location of the threshold values of the characteristic parameter may be calculated as 740. When the number of bootstrap samples is 10⁶, the mean location of the threshold values of the characteristic parameter may be calculated as 866. When the number of bootstrap samples is 10⁷, the mean location of the threshold values of the characteristic parameter may be calculated as 945. However, the mean location values described above are only examples, and are not limited thereto.

Referring to FIG. 10, it is assumed that the true value is 949.21 [kΩ]. Referring to the calculation result as an example, when the number of sample data # of Samples is 10⁵, the mean location of the threshold values of Rtotal of DRAM may be 740 [kΩ], the standard deviation of the threshold values of Rtotal of DRAM may be 60 [kΩ], and the time required to estimate the threshold values of Rtotal of DRAM (hereinafter, required time) may be 70 [s]. When the number of sample data # of Samples is 10⁶, the mean location of the threshold values of Rtotal of DRAM may be 866 [kΩ], the standard deviation of the threshold values of Rtotal of DRAM may be 45 [kΩ], and the required time for the threshold values of Rtotal of DRAM may be 270 [s]. When the number of sample data # of Samples is 10⁷, the mean location of the threshold values of Rtotal of DRAM may be 945 [kΩ], the standard deviation of the threshold values of Rtotal of DRAM may be 20 [kΩ], and the required time for the threshold values of Rtotal of DRAM may be 2574 [s]. When the number of sample data # of Samples is 10⁵, the mean error versus the true value may be −22.04 [%]. When the number of sample data # of Samples is 10⁶, the mean error versus the true value may be −8.76 [%]. When the number of sample data # of Samples is 10⁷, the mean error versus the true value may be −0.44 [%]. However, the above values are only examples, and are not limited thereto.

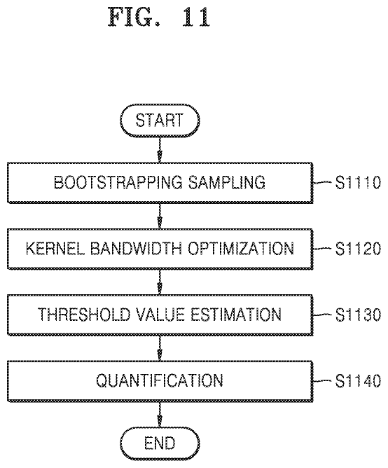

FIG. 11 is a flowchart for illustrating a method according to some implementations.

Referring to FIGS. 1 to 11, a bootstrapping sampling operation is performed (S1110). For example, the estimation device 120 may sample a plurality of sample data sets based on the simulation data set. Operation S1110 according to some implementations is similar to the operations described above with reference to FIG. 3B.

A kernel bandwidth optimization operation is performed (S1120). For example, the estimation device 120 may estimate an optimal kernel bandwidth for each sample data set by using a bandwidth estimation method selected according to the number of sample data included in each sample data set from among a plurality of bandwidth estimation methods. Operation S1120 according to some implementations is similar to the operations described above with reference to FIG. 7.

A threshold value estimation operation is performed (S1130). For example, the estimation device 120 may estimate threshold values of a plurality of sample data sets based on optimal kernel bandwidths estimated for each of the plurality of sample data sets. The threshold value may correspond to the tail region of the kernel density function.

A quantification operation is performed (S1140). For example, the estimation device 120 may provide a quantitative value in which the uncertainty of the threshold values is quantified based on the threshold values of the plurality of sample data sets. In operation S1140 according to some implementations, the quantitative value may be calculated as the mean of the threshold values of the plurality of sample data sets. In operation S1140 according to some other implementations, the quantitative value may be calculated as a standard deviation of the threshold values of the plurality of sample data sets.

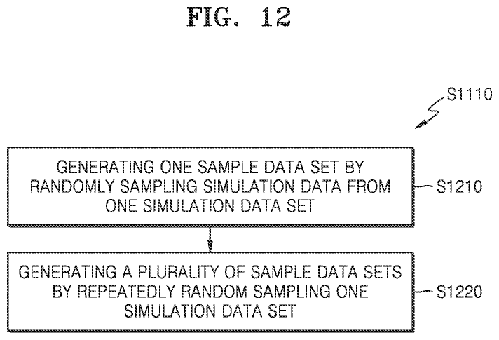

FIG. 12 is a flowchart for illustrating some implementations of operation S1110.

Referring to FIGS. 1, 3B, and 12, operation S1110 may include operations S1210 and S1220.

In operation S1210, the estimation device 120 may generate one sample data set including k sample data by randomly sampling simulation data from one simulation data set. Referring to FIG. 3B, for example, one simulation data set may correspond to one MCS set 313b, the simulation data may correspond to MCS samples or MCS sample data, and one sample data set may correspond to one bootstrap set (e.g., first bootstrap set 321b_1). The sampling module 320b may generate the first bootstrap set 321b_1 by randomly sampling k MCS samples from the MCS set 313b.

In operation S1220, the estimation device 120 may generate a plurality of sample data sets each including the same number of sample data by repeatedly performing a random sampling operation on one simulation data set. Referring to FIG. 3B, for example, the sampling module 320b may generate the plurality of bootstrap sets 321b_1, 321b_2, and 321b_N by repeatedly performing the random sampling operation.

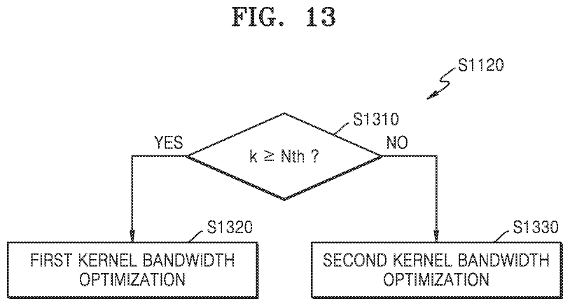

FIG. 13 is a flowchart for illustrating some implementations of operation S1120.

Referring to FIGS. 1, 7, and 13, operation S1120 includes operations S1310, S1320, and S1330. Operation S1320 may be referred to as a first kernel bandwidth optimization operation, and operation S1330 may be referred to as a second kernel bandwidth optimization operation.

In operation S1310, the estimation device 120 may compare the number of sample data included in each sample data set with the reference number. Referring to 710 of FIG. 7, for example, the optimization module 700 compares the number of sample data (e.g., k) included in one sample data set DS_SMP with the reference number Nth.

The number of sample data may be greater than or equal to the reference number. The sample data set including sample data greater than or equal to the reference number Nth may be referred to as a first sample data set. In operation S1320, the estimation device 120 may estimate a first kernel bandwidth for the first sample data set using the first bandwidth estimation method.

The number of sample data may be less than the reference number. The sample data set including a less number of sample data than the reference number may be referred to as a second sample data set. In operation S1330, the estimation device 120 may estimate a second kernel bandwidth for the second sample data set using the second bandwidth estimation method.

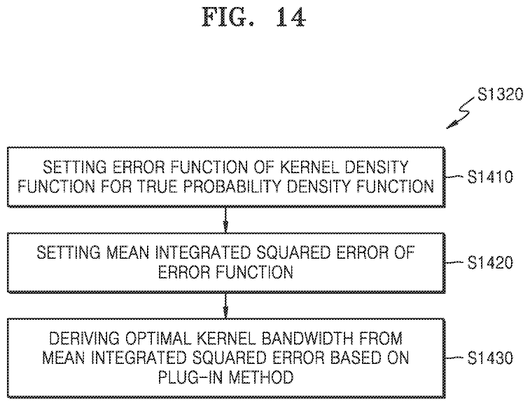

FIG. 14 is a flowchart for illustrating some implementations of operation S1320.

Referring to FIGS. 7 and 14, operation S1320 includes operations S1410, S1420, and S1430.

In operation S1410, the optimization module 700 may set an error function of the kernel density function for the true PDF. The error function of operation S1410 may be expressed as Equation 4 described above.

In operation S1420, the optimization module 700 may set a mean integrated squared error of the error function. The MISE of the error function in operation S1420 may be expressed as Equation 5.

In operation S1430, the optimization module 700 may derive an optimal kernel bandwidth from the MISE based on the plug-in rule method. In some implementations, the first bandwidth estimation method of FIG. 13 is the plug-in rule method, and the first kernel bandwidth may be calculated as Equation 6 described above.

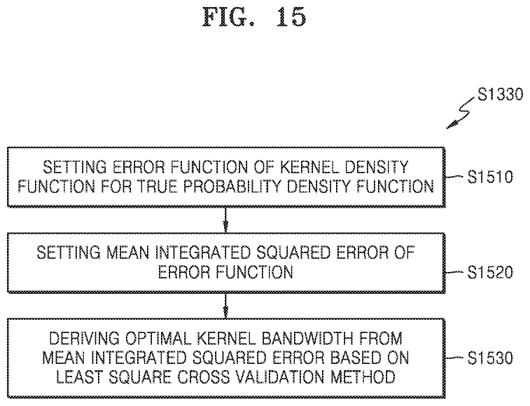

FIG. 15 is a flowchart for illustrating some implementations of operation S1340.

Referring to FIGS. 7 and 15, operation S1330 includes operations S1510, S1520, and S1530.

Operation S1510 may be the same as operation S1410. The error function of operation S1510 may be expressed as Equation 4 described above. Operation S1520 may be the same as operation S1420. The MISE of the error function in operation S1520 may be expressed as Equation 5.

In operation S1530, the optimization module 700 may derive an optimal kernel bandwidth from the MISE based on the LSCV method. In some implementations, the second bandwidth estimation method performed in the operations of FIG. 13 is the LSCV method, and the second kernel bandwidth may be calculated as Equation 8 described above.

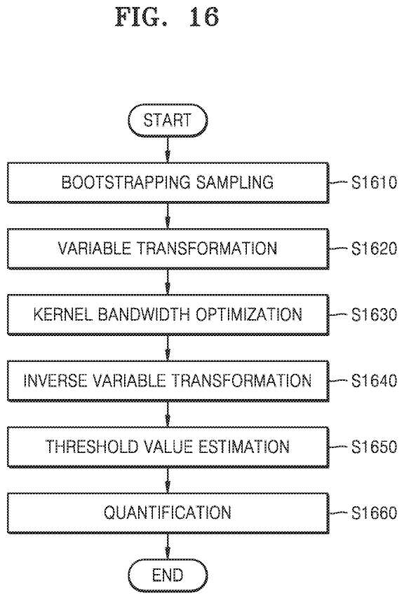

FIG. 16 is a flowchart for illustrating a method according to some implementations.

Referring to FIGS. 1 to 16, the method of FIG. 16 includes operations S1610, S1620, S1630, S1640, S1650, and S1660.

Operations S1610, S1630, S1650, and S1660 are as described above with reference to operations S1110, S1120, S1130, and S1140 of FIG. 11.

A variable transformation operation is performed (S1620). In operation S1620, the estimation device 120 may set a transformed kernel density function defined based on the domain of the transformation function based on the kernel function and the transformation function. The transformation function may be a function that changes the domain of the kernel function for the plurality of sample data sets. The transformation function may be expressed as Equation 2 described above with reference to FIG. 5.

An inverse variable transformation operation is performed (S1640). In operation S1640, the estimation device 120 may calculate the optimal kernel bandwidth of the kernel density function from the optimal kernel bandwidth of the transformed kernel density function based on the inverse transformation function corresponding to the transformation function and the kernel function. The transformed kernel density function may be expressed as Equation 3 described above with reference to FIG. 5. The inverse transformation function may be an inverse function of the transformation function according to Equation 2.

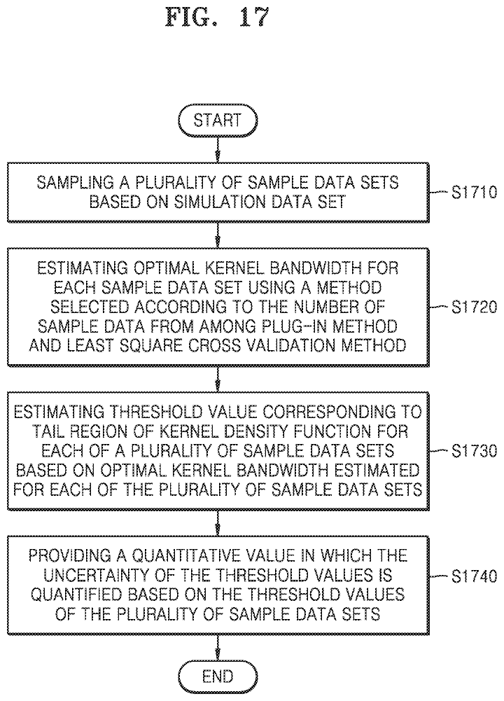

FIG. 17 is a flowchart for illustrating a method according to some implementations.

Referring to FIG. 17, an operation of sampling a plurality of sample data sets based on the simulation data set is performed (S1710). The simulation data set may include a plurality of simulation data for physical quantities of the product.

An operation of estimating an optimal kernel bandwidth for each sample data set is performed using a method selected according to the number of sample data from among the plug-in rule method and the LSCV method (S1720).

Based on optimal kernel bandwidths estimated for each of the plurality of sample data sets, an operation of estimating the threshold value corresponding to the tail region of the kernel density function for each of the plurality of sample data sets is performed (S1730).

An operation of providing a quantitative value in which the uncertainty of the threshold values is quantified based on the threshold values of the plurality of sample data sets is performed (S1730).

As described above, by using the optimal bandwidth estimation method according to the number of sample data, it is possible to accurately estimate the threshold value, tail region, and kernel bandwidth of the kernel density function.

In addition, as described above, by estimating the threshold value, tail region, and kernel bandwidth of the kernel density function even with a relatively small number of sample data, it is possible to reduce TAT and resources for estimation.

The disclosed implementations may be implemented in the form of a recording medium storing instructions executable by a computer. The instructions may be stored in the form of program codes, and when executed by a processor, create program modules to perform operations of the disclosed implementations. The recording medium may be implemented as a computer-readable recording medium.

The computer-readable recording medium includes all types of recording medium in which instructions that can be decoded by a computer are stored. For example, there may be read only memory (ROM), random access memory (RAM), magnetic tape, magnetic disk, flash memory, optical data storage device, and the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the inventive concept has been particularly shown and described with reference to implementations thereof, it will be understood that various changes in form and details may be made therein without departing from the spirit and scope of the following claims.

1. A method comprising:
sampling a plurality of sample data sets based on a simulation data set including a plurality of simulation data for a characteristic parameter of a product;
estimating an optimal kernel bandwidth for each sample data set of the plurality of sample data sets by using a bandwidth estimation method selected, from among a plurality of bandwidth estimation methods configured to optimize a kernel bandwidth of a kernel density function with respect to defects of the product, according to a number of samples included in each sample data set of the plurality of sample data sets;
estimating a threshold value corresponding to a tail region of the kernel density function for each sample data set of the plurality of sample data sets based on optimal kernel bandwidths estimated for each sample data set of the plurality of sample data sets; and
providing, based on the threshold values of the plurality of sample data sets, a quantitative value in which uncertainty of the threshold values corresponding to the tail region of the kernel density function is quantified.

2. The method of claim 1,
wherein sampling the plurality of sample data sets comprises
generating a first sample data set including k sample data by randomly sampling simulation data from one simulation data set, wherein k is an integer greater than 1; and
generating the plurality of sample data sets each including same number of samples by repeatedly performing random sampling on the one simulation data set.

3. The method of claim 1,
wherein estimating the optimal kernel bandwidth comprises
comparing the number of samples included in each sample data set with a reference number;
estimating a first kernel bandwidth for a first sample data set including a first number of samples greater than or equal to the reference number by performing a first bandwidth estimation; and
estimating a second kernel bandwidth for a second sample data set including a second number of samples less than the reference number by performing a second bandwidth estimation.

4. The method of claim 3,
wherein estimating the first kernel bandwidth comprises
setting an error function of the kernel density function for a true probability density function;
setting a mean integrated squared error of the error function; and
deriving the optimal kernel bandwidth from the mean integrated squared error by using a plug-in rule method.

5. The method of claim 3,
wherein estimating the second kernel bandwidth comprises
setting an error function of the kernel density function for a true probability density function;
setting a mean integrated squared error of the error function; and
deriving the optimal kernel bandwidth from the mean integrated squared error by using a least square cross validation method.

6. The method of claim 1,
wherein providing the quantitative value comprises calculating the mean of threshold values of the plurality of sample data sets as the quantitative value.

7. The method of claim 1,
wherein, providing the quantitative value comprises calculating a standard deviation of threshold values of the plurality of sample data sets as the quantitative value.

8. The method of claim 1, further comprising:
setting, based on a kernel function for the plurality of sample data sets and a transformation function that changes a domain of the kernel function, a transformed kernel density function defined on the basis of a domain of the transformation function; and
calculating an optimal kernel bandwidth of the kernel density function from an optimal kernel bandwidth of the transformed kernel density function, based on an inverse transformation function corresponding to the transformation function and the kernel function.

9. An electronic device comprising one or more processors coupled to a memory storing instructions that, when executed, cause the one or more processors to perform operations comprising:
sampling a plurality of sample data sets based on a simulation data set generated as a simulation result regarding a characteristic parameter of a product;
estimating an optimal kernel bandwidth for each of the plurality of sample data sets by using a bandwidth estimation method selected, from among a plurality of bandwidth estimation methods configured to optimize a kernel bandwidth of a kernel density function with respect to defects of the product, according to the number of samples included in each of the plurality of sample data sets;
estimating a threshold value corresponding to a tail region of the kernel density function for each of the plurality of sample data sets based on optimal kernel bandwidths estimated for each of the plurality of sample data sets; and
providing, based on the threshold values of the plurality of sample data sets, a quantitative value in which uncertainty of the threshold values corresponding to a tail region of the kernel density function is quantified.

10. The electronic device of claim 9,
wherein estimating the optimal kernel bandwidth comprises
comparing a number of samples included in each of plurality of sample data sets with a reference number, and
estimating the optimal kernel bandwidth for each sample data set using one of a first bandwidth estimation method and a second bandwidth estimation method selected according to a comparison result.

11. The electronic device of claim 10,
wherein the first bandwidth estimation method is a plug-in rule method, and
the second bandwidth estimation method is a least square cross validation method.

12. The electronic device of claim 11,
wherein estimating the optimal kernel bandwidth comprises
deriving the optimal kernel bandwidth using the plug-in rule method when the number of samples included in each of the plurality of sample data sets is greater than or equal to the reference number, and
deriving the optimal kernel bandwidth using the least square cross validation method when the number of samples included in each sample data set is less than the reference number.

13. The electronic device of claim 9,
wherein providing the quantitative value comprises
calculating the mean of threshold values of the plurality of sample data sets as the quantitative value.

14. The electronic device of claim 9,
wherein providing the quantitative value comprises
calculating a standard deviation of threshold values of the plurality of sample data sets as the quantitative value.

15. The electronic device of claim 9, wherein the operations further comprise
setting, based on a kernel function for the plurality of sample data sets and a transformation function that changes the domain of the kernel function, a transformed kernel density function defined on the basis of a domain of the transformation function; and
calculating an optimal kernel bandwidth of the kernel density function from an optimal kernel bandwidth of the transformed kernel density function based on an inverse transformation function corresponding to the transformation function and the kernel function.

16. A system comprising one or more processors coupled to a memory storing instructions that, when executed, cause the one or more processors to perform operations comprising:
generating a simulation data set comprising a plurality of simulation data for a characteristic parameter of a product by performing simulation regarding the characteristic parameter of the product; and
estimating threshold values corresponding to a tail region of a kernel density function with respect to defects of the product based on the simulation data set,
wherein estimating the threshold values comprises
sampling a plurality of sample data sets from the simulation data set,
estimating an optimal kernel bandwidth for each of the plurality of sample data sets by using a bandwidth estimation method selected according to a number of samples included in each of the plurality of sample data sets from among a plurality of bandwidth estimation methods configured to optimize the kernel bandwidth of the kernel density function,
estimating the threshold value for each of the plurality of sample data sets based on optimal kernel bandwidths estimated for each of the plurality of sample data sets, and
generating a quantitative value quantifying uncertainty of the threshold values based on the threshold values of the plurality of sample data sets.

17. The system of claim 16,
wherein estimating the threshold values comprises
comparing the number of samples included in each of the plurality of sample data sets with a reference number, and
estimating the optimal kernel bandwidth for each of the plurality of sample data sets using one of a first bandwidth estimation method and a second bandwidth estimation method selected according to a comparison result.

18. The system of claim 17,
wherein the first bandwidth estimation method is a plug-in rule method, and
the second bandwidth estimation method is a least square cross validation method,
wherein estimating the threshold values comprises
deriving the optimal kernel bandwidth using the plug-in rule method when the number of samples included in each of the plurality of sample data sets is greater than or equal to the reference number, and
deriving the optimal kernel bandwidth using the least square cross validation method when the number of sample data included in each of the plurality of sample data sets is less than the reference number.

19. The system of claim 16,
wherein estimating the threshold values comprises
calculating at least one of the mean and the standard deviation of threshold values of the plurality of sample data sets as the quantitative value.

20. The system of claim 16,
wherein estimating the threshold values comprises
setting, based on a kernel function for the plurality of sample data sets and a transformation function that changes the domain of the kernel function, a transformed kernel density function defined on the basis of a domain of the transformation function, and
calculating an optimal kernel bandwidth of the kernel density function from an optimal kernel bandwidth of a transformed kernel density function based on an inverse transformation function corresponding to the transformation function and the kernel function.

21. (canceled)
